(19) United States
(12) Patent Application Publication
(10) Pub. No.: US 2008/0079450 A1
(43) Pub. Date: Apr. 3, 2008

(54) Intelligent probe chips/heads

(76) Inventors: Vada W. Dean, Morgan Hill, CA (US); Mark L. DiOrio, Cupertino, CA (US)

Correspondence Address: PATENT LAW OFFICES OF DAVID MILLERS, 1221 Sun Ridge Road, Placerville, CA, 95667, US

(21) Appl. No.: 11/977,698

(22) Filed: Oct. 24, 2007

Related U.S. Application Data
(63) Continuation of application No. 11/165,679, filed on Jun. 24, 2005.
(60) Provisional application No. 60/582,758, filed on Jun. 24, 2004.

(51) Int. Cl. G01R 1/02; G01R 31/26

(52) U.S. Cl. 324/754; 324/758; 324/759

(57) ABSTRACT

An intelligent probe chip or probe head can include design-for-test (DFT) circuitry that would otherwise be required in a device being tested and/or implement testing functions so that less-expensive automated test equipment (ATE) can test the device. Further, the probe chip or probe head can generate high frequency signals, avoiding the need to transmit high frequency signals the longer distance from the ATE.

### CROSS-REFERENCE TO RELATED APPLICATION

This is a continuation of U.S. patent application Ser. No. 11/165,679, filed Jun. 24, 2005, which claims benefit of the earlier filing date of U.S. Provisional Pat. App. 60/582,758 filed Jun. 24, 2004, which are hereby incorporated by reference in its entirety.

### BACKGROUND

Testing of integrated circuits and semiconductor devices is critical to production of functional devices having a commercially valuable useful life. FIG. 1 schematically illustrates a conventional test configuration in which automated test equipment (ATE) 110 tests a semiconductor integrated circuit 140. Integrated circuit 140 can be a portion of a processed semiconductor wafer or alternatively be a separate die produced after sawing of a wafer. A probe card 120 and associated probe tips 121 provide electrical connections between integrated circuit 140 and ATE 110 during testing.

ATE 110 is generally a complex and expensive testing system that implements a variety of different test functions for testing of integrated circuits such as memory or processing circuits. To be able to test many types of devices, ATE 110 includes functionality that is required for some types of devices but is unnecessary for testing other types of devices. ATE 110 in FIG. 1 particularly includes power supplies 112, mechanical and cooling systems 114, timing signal and pattern generators 115, data sources 116, pin electronics 117, and a controller or CPU with executable software 118 for use in automated testing processes of integrated circuits 140 and similar devices.

Integrated circuit 140 normally contains device circuitry 142 that implements the functions of integrated circuit 140 and therefore needs to be tested for functionality, performance grading, and useful life. Integrated circuit 140 or the wafer containing integrated circuit 140 may additionally include design-for-test (DFT) circuitry 144 that is solely used for testing and repair. DFT circuitry 144 may, for example, implement specialized testing functions that are not available in ATE 110.

Use of DFT circuitry 144 can reduce the cost of testing by allowing simpler test equipment (i.e., test equipment with less functionality) to perform the required testing of IC 140. FIG. 2 illustrates the relative costs of different types of test equipment and the percentage of cost associated with implementing different test functionality. For example, full-function test equipment that implements all the required test functionality to test a memory IC may require a high pin count. Full-function test equipment with a high pin count, e.g., 304 test pins that contact I/O pads and internal test pads, is currently expensive. However, the cost of the required test equipment can be reduced dramatically if DFT circuitry 144 in the device 140 being tested can implement internal tests so that a 152-pin structural tester, a 152-pin maximal BIST, or a 64-pin simple BIST provides sufficient testing functionality.

A drawback of including DFT circuitry 144 in an IC 140 or on a wafer is that DFT circuitry 144 can consume a significant amount (e.g., 5%) of the wafer area, and therefore increases production costs by reducing the number of devices that can be fabricated on a wafer. A reduction in test cost without significant consumption of wafer area would be preferable.

### SUMMARY

In accordance with an aspect of the invention, an intelligent probe chip, probe head, or probe card can include design-for-test (DFT) circuitry that would otherwise be required in the device under test and/or can implement testing functions so that less-expensive automated test equipment (ATE) can test the device.

### BRIEF DESCRIPTION OF THE DRAWINGS

FIG. 1 shows a conventional configuration for testing of an integrated circuit.

FIG. 2 illustrates the relationship of cost to the level of functionality of automated test equipment.

FIG. 3 shows a configuration for testing an integrated circuit using an intelligent probe chip in accordance with an embodiment of the invention.

FIG. 4 illustrates a process for fabrication of an intelligent probe card or chip in accordance with an embodiment of the invention.

FIGS. 5A and 5B respectively show top and bottom views of a probe head in accordance with an embodiment of the invention including active circuitry.

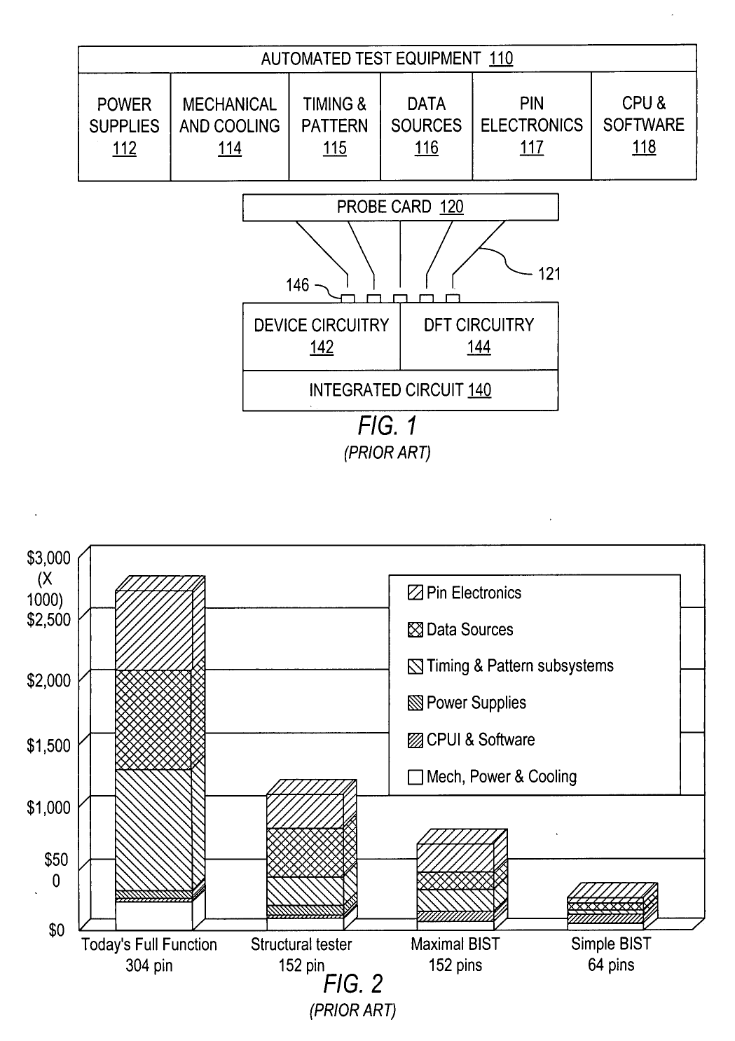

Use of the same reference symbols in different figures indicates similar or identical items.

### DETAILED DESCRIPTION

In accordance with an aspect of the invention, a probe chip or probe head on which probe tips are fabricated, affixed, or pressed against can further include test circuits that implement functions that would otherwise need to be implemented in automated test equipment (ATE) or in design-for-test (DFT) circuitry in a device under tested. Placing such circuitry on a probe head or probe chip can reduces the lengths of lines transmitting high frequency signals to the relatively short distance between the device under test and the probe chip or probe head. In contrast, prior systems have required either DFT circuits on the device or transmission of high frequency signals over the relatively longer distances between the ATE and the device.

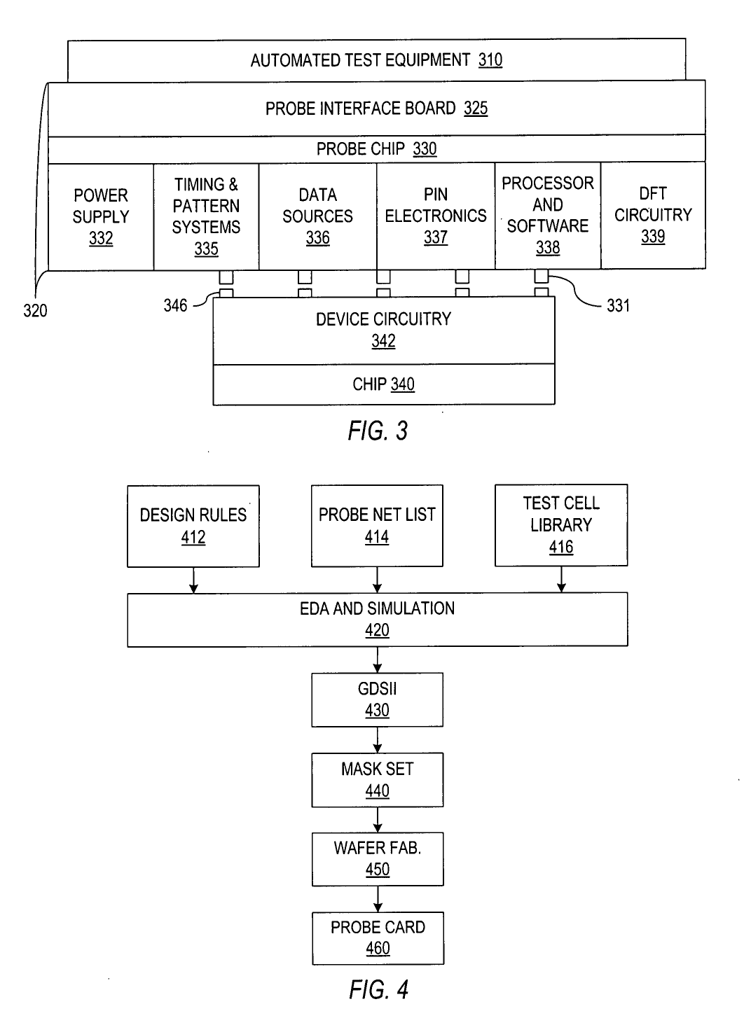

FIG. 3 illustrates a configuration for automated test equipment (ATE) 310 to test a device or devices 340. Device or devices 340 can be included on one or more portions of a processed semiconductor wafer, or alternatively, a device 340 can be an integrated circuit die produced after separation from a wafer. Each device 340 has contacts 346 for input and output of electrical signals. Each contact 346 generally includes a metal pad such as a bonding pad and may further include conductive bumps such as a solder ball residing on the bonding pad. In a preferred embodiment, contacts 346 on device 340 include bumps with sufficient malleability for a probe and planarize process as described further below.

A probe card 320 is connected to ATE 310 and includes a probe interface board 325 and a probe head, which in FIG. 3 includes of a probe chip 330 with integrated probe tips 331. Probe tips 331 provide electrical connections to contacts 346 on the device or devices 340 being tested. FIG. 3 illustrates an exemplary embodiment including a single probe chip 330 for testing a single device 340. Alternatively, the probe head may include a single probe chip 330 for parallel testing of multiple devices 340 on a wafer, or multiple probe chips 330 for testing of one or more devices 340. The following describes the illustrated embodiment using a single probe chip 330 to test a single device 340. However, alternative embodiments of the invention including multiple probe chips or parallel testing of multiple devices can use similar techniques.

For the embodiment of FIG. 3, probe chip 330 is preferably an integrated circuit device of a similar composition to the tested device 340, so that probe chip 330 has thermal properties that are similar to the thermal properties of device 340. Accordingly, the pitch of probe tips 331 on probe chip 330 expands and contracts with temperature changes in the same manner as the pads on device 340. Probe tips 331 can therefore provide good electrical connections even when the temperature of the system changes. Probe chip 330 and probe tips 331 can provide a relatively rigid structure with flat or shaped contact areas that can be applied to malleable bumps on contacts 346. When sufficient pressure to provide good electrical contact for testing, probe tips 331 deform the malleable bumps causing inelastic deformations of the bumps that improve the planarity of the tops of the bumps.

Probe interface board 325 can be a printed circuit board that provides electrical connections between probe chip 330 and ATE 310 and is only required if probe chip 330 cannot be directly connected to ATE 310. In one embodiment, probe interface board 325 includes a socket into which probe chip 330 can be inserted. This allows replacement of probe chip 330 if probe chip 330 or probe tips 331 become worn or damaged or changing of probe chip 330 for testing of a different type of device. U.S. patent application Ser. No. 10/718,031, entitled “Device Probing Using A Matching Device”, filed Nov. 19, 2003, which is hereby incorporated by reference in its entirety, further describes suitable structures for probe interface board 325.

Probe chip 330 can be a semiconductor device that is fabricated using conventional integrated circuit processing techniques and can include active circuitry that implements test functions. For example, probe chip 330 can include circuit blocks that provide power supply 332, timing and pattern systems 335, data sources 336, pin electronics 337, a processor and software or firmware 338, and general DFT circuitry 339 for execution of testing processes on device 340. Power supply systems 332 generally act to distribute power and ground signals to the device under test and may additionally include active circuits such as voltage regulators and charge pumps. Timing and pattern systems 335 can be implement to generate the specific timing signals or patterns that are required for testing of the device. Data source 336 can be implemented using memory with associated circuitry for production of data, for example, for testing of memory devices or devices with embedded memory. Pin electronics 337 can provide general control the electrical signals or characteristics of probe tips 331. Each channel of the pin electronics 337 may, for example, include active circuitry such as a multi-level pin driver, one or more comparators, variable clamps, and an active load. Processor 338 can be used for local control of testing of device 340. An advantage of including such local control on a probe chip or probe head is the ability to customize a probe card for complex testing routines without requiring complex ATE.

As a result of including active test circuitry on a probe chip or probe head, the wafer area required for device 340 can be effectively reduced since DFT circuitry in device 340 or on the wafer containing device 340 can be reduced or eliminated. In particular, device 340 and/or a wafer that contains device 340 may contain only circuits 342 that implement the functions of device 340 without any test circuits that are not needed in the finished product. Additionally, ATE 310 can be relatively simple and therefore less-expensive test equipment because specific functionality required for testing of a specific device is implemented in probe chip 330. Even a partial inclusion of some of power supply 332, timing and pattern systems 335, data sources 336, pin electronics 337, a CPU and software 338, and general DFT circuitry 339 in probe chip 330 with the remainder of such circuits being in ATE 310 or device 340 can still reduce testing cost and/or reduce the circuit area of device 340.

FIG. 4 illustrates a process for fabrication of a probe chip/card in accordance with an embodiment of the invention. A probe chip in accordance with the illustrated embodiment of the invention can be constructed using design rules 412 that are preferably selected for consistency with the device to be tested. A probe net list 414 defines the locations of probe tips (e.g., probe tips 331) that can be set in a pattern matching contacts on the device to be tested. Net list 414 can further indicate the positions of bond pads or other electrical contact structures for connection to automated test equipment or to an intervening probe interface board. A test cell library 416 can then be used for active circuit modules that are fabricated in and on the probe chip. Test cell library 416 will generally include circuit modules that are specific to the device to be tested and modules that are specific to the particular automated test equipment to which the probe chip will be connected. Test cell library 416 can include circuit blocks for power supply, timing and pattern systems, data sources, pin electronics, a processor and software, and general DFT circuitry to name a few.

Electronic design automation (EDA) and simulations 420 and Graphic Design System II File Format (GDSII) 430 can be used to generate a mask set 440 of the probe chip. A wafer fabrication facility 450 that is similar to or the same as the facility that produces the devices to be tested can then produce the probe chips. However, if desired, the probe chips may be further processed to create bumps that serve as probe tips that contact the device being tested. The probe chip can then be attached to a probe interface board 325 for use with the corresponding automated test equipment.

In one embodiment of the invention, a probe chip fabrication process can form one or more layers of metal traces for a space transformer on insulating layers such as layers of polymer material. A polysilicon layer can then be deposited on the space transformer and processed to create transistors and other elements of the active circuitry that implements the functions of the probe chip. Typically, the circuitry on the probe chip will be less complex or otherwise require less area than the circuitry in the device being tested. Accordingly, the level of integration in the probe chip can be lower than the level of integration used in the device. Probe tips can be formed on the semiconductor or on the space transformer structures.

The testing systems and methods in accordance with specific embodiments of the invention can provide significant advantages over conventional probing and test systems. One advantage is that a conventional mechanical probe head can be replaced with a probe chip that provides improved durability and easier cleaning. Additionally, fabrication techniques for the probe chips are substantially the same as device fabrication techniques and can scale with industry economics and technology. Further, the probe chips migrate test circuitry from ATE to probe chips, reducing ATE costs, possibly extending the useful life of ATE, and also minimize DFT circuit consumption of wafer area by transferring overhead to reusable probe chips. Less expensive automated test equipment implementing only a minimum set of test functions can be used with an intelligent probe chip that implements specialized test procedures that are required for a specific device being tested, and the automated test equipment can be adapted to test different devices simply through a change of the probe chip. In contrast, conventional testing often uses expensive test equipment that may implement test functions that are unnecessary for testing of some devices.

Many of the advantages of integrating probe tips and test circuitry on a probe chip as described above can be achieved through fabrication of a probe head in which probe tips and test circuits are separate devices. In particular, placing test circuits on the probe head allows complex and customized testing without requiring complex and expensive ATE and provides short signal paths for high frequency signals.

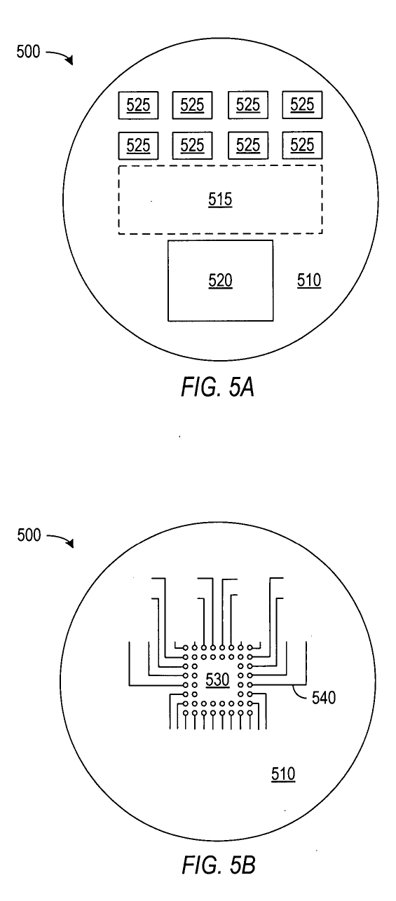

FIGS. 5A and 5B respectively show top and bottom views of a probe head 500 in accordance with an embodiment of the invention including active circuitry 520 and 525 on a top surface of an interconnect substrate 510 and an array of probe tips 530 on a bottom surface. The active circuits on probe head 500 can include one or more chips or integrated circuit that are electrically connected to substrate 510.

Substrate 510 in an exemplary embodiment of the invention is a printed circuit board to which devices 520 and 525 attach. Substrate 510 also includes contacts (not shown) for electrical connections to a probe interface board (not shown) in a probe card (not shown). Conductive traces 540 in and on probe head 500 electrically connect active circuits 520 and 525 to probe tips 530 on a bottom side of probe head 510.

Probe tips 530 contact and make electrical connection to the device under test and be conventional probing structure such as pogo pins or cantilevered or spring-loaded needles. In an exemplary embodiment of the invention, probe tips 530 are rigid conductive bumps that are supported by a stiffened portion 515 of substrate 510. Flat-topped or shaped probe tips as described above can be used in a probe and planarize process.

In an exemplary embodiment illustrated in FIG. 5A, the active circuits include a transceiver 520 such as a XAUI or an Ethernet transceiver and a MEMS controlled switching array 525. Transceiver 520 can communicate with a device under test using high frequency signals such as required for testing of a 10-Gigabit Ethernet system. Such high-frequency signals might otherwise be difficult to generate and transmit between ATE and the device under test. Switching array 525, which can operate under the control of the ATE (not shown) or transceiver 520, can implement pin electronics functions for high frequency signal relaying or multiplexing.

Although the invention has been described with reference to particular embodiments, the description is only an example of the invention's application and should not be taken as a limitation. Various adaptations and combinations of features of the embodiments disclosed are within the scope of the invention as defined by the following claims.

What is claimed is:

1. A test system comprising a probe chip that includes:
a substrate;
active test circuitry integrated in and on the substrate; and
probe tips on the substrate and connected to the active test circuitry, wherein
the active test circuitry generates an output signal on an least one of the probe tips, the output signal having a frequency higher than frequencies of any input signal to the probe chip.

2. The test system of claim 1, wherein the active circuitry comprises a transceiver that generates the output signal.

3. The system of claim 2, wherein the transceiver is selected from a group consisting of a XAUI, an Ethernet transceiver, and a MEMS controlled switching array.

4. The system of claim 1, wherein the probe tips have a pattern that matches a pattern of electrical contacts on a device being tested.

5. The system of claim 4, wherein the probe tips are sufficiently rigid that a pressure used when the probe tips contact the electrical contacts for testing deforms and planarizes tops of the electrical contacts.

6. The system of claim 1, further comprising automated test equipment that is electrically connected to the probe chip and provides the input signals to the probe chip.

7. The system of claim 6, wherein the automated test equipment controls the active circuitry to direct the active circuitry to communicate with a device under test at frequencies higher than the frequencies of the input signals.

8. The system of claim 1, wherein the probe chip further comprises passive circuitry that implements a space transformation from electrical connections of a probe interface board to electrical connections of a device being tested.

9. The system of claim 1, wherein the probe chip is a semiconductor device.

10. The system of claim 1, wherein the active test circuitry comprises a signal generator that controls a pattern of the output signal.

11. The system of claim 1, where in the active test circuitry comprises memory storing data for testing of devices.

12. The system of claim 1, wherein the active test circuitry comprises a processor and memory storing software that the processor executes to perform testing routines independently of the other equipment in the test system.

13. A probe head comprising:
a substrate;
probe tips attached to the substrate; and
active circuitry mounted on the substrate and electrically connected to the probe tips through the substrate, wherein the active circuitry generates an output signal an output signal on an least one of the probe tips, the output signal having a frequency higher than frequencies of any input signal to the probe head.

14. The probe head of claim 13, wherein the substrate comprises a printed circuit board.

15. The probe head of claim 13, further comprising a control circuit mounted on the substrate.

16. The probe head of claim 13, wherein the active circuitry comprises a transceiver.

17. The probe head of claim 13, wherein the active circuitry comprises a MEMS-controlled switching array.
